(19) United States
(12) Patent Application Publication
(10) Pub. No.: US 2025/0185186 A1
(43) Pub. Date: Jun. 5, 2025

(54) DEVICE WITH EXCHANGEABLE ELECTRONICS ASSEMBLIES OF A MOTOR VEHICLE

(71) Applicant: Robert Bosch GmbH, Stuttgart (DE)

(72) Inventors: Andreas LANG, Beilstein-Schmidhausen (DE); Dominik DORBATH, Plymouth, MI (US); Edward LEIGH, Bad Lippspringe (DE); Franz-Josef WOLLSCHEID, Plochingen (DE); Marcel RUDOLPH, Renningen (DE); Markus KIRSCHNER, Schorndorf (DE); Rainer SCHITTENHELM, Ilvesheim (DE); Robert KORNHAAS, Spraitbach (DE)

(21) Appl. No.: 18/840,170

(22) PCT Filed: Mar. 2, 2023
(86) PCT No.: PCT/EP2023/055263

§ 371 Date: Aug. 21, 2024

(30) Foreign Application Priority Data
Mar. 31, 2022 (DE) 10 2022 203 151.2

(51) Int. Cl. H05K 5/00; B60R 16/023; H05K 5/03

(52) U.S. Cl. CPC H05K 5/0069; B60R 16/0239; H05K 5/03

(57) ABSTRACT

A device with exchangeable electronics assemblies of a motor vehicle. The device includes at least one housing for at least partially enclosing the at least two exchangeable electronics assemblies, at least one front side which is detachably connected to the housing and via which the exchangeable electronics assemblies arranged inside the housing can be accessed, wherein a rear housing cover and a rear printed circuit board, which is aligned transversely to the electronics assemblies and serves to contact the at least two exchangeable electronics assemblies, are provided, wherein at least one of the exchangeable electronics assemblies includes at least one carrier board with an infrastructure and at least one module, connected to the carrier board, with at least one computing unit, in particular a processor.

### FIELD

The present invention relates to a device with exchangeable electronics assemblies of a motor vehicle.

### BACKGROUND INFORMATION

German Patent Application No. DE 10105292 A1 describes a central vehicle-assembly mounting structure with an electrical connection, in which a plurality of electrical units, which are arranged almost centrally in the transverse direction of a vehicle dashboard, for example an audio unit, a display unit, a navigation unit and an air-conditioning operation unit, are combined to form an integral structure as an assembly.

German Patent Application No. DE 10244607 A1 describes an electronic control unit, in particular racks with slots for externally ventilated plug-in assemblies.

An object of the present invention is to further increase the flexibility of the device. This object is achieved by certain features of the present invention.

### SUMMARY

Due to modularization, the device according to an example embodiment of the present invention achieves parallel testability, resulting in test time reduction and increased flexibility. The modular concept also supports faster and more cost-effective development of successor devices. In particular, the mechanics may remain the same, while the connector board or front panel can be changed. Depending on the requirements, certain modules, in particular the computing modules or infrastructure, can be carried over or purposefully exchanged. The use of standard modules facilitates exchangeability. A change or increase in the computing power is easily possible, in particular by exchanging the computing module. The solution is also characterized by high scalability with regard to the interfaces and by high performance. In addition, the solution makes high flexibility with regard to the type of computing units, the interfaces, and the safety requirements or availability requirements possible. The device can serve as an integration platform for easy integration of additional functions, such as data recording, etc.

Further expedient developments of the present invention arise from the disclosure therein.

### BRIEF DESCRIPTION OF THE DRAWINGS

FIG. 1 shows a total perspective exploded view of an exemplary embodiment of a device with multiple exchangeable electronics assemblies, according to the present invention.

FIG. 2 shows a block diagram of a logical partitioning of the device, according to an example embodiment of the present invention.

FIG. 3 shows a further block diagram of a logical partitioning with multiple exchangeable electronics assemblies, according to an example embodiment of the present invention.

FIG. 4 shows an overview of a module according to an example embodiment of the present invention with respect to the connectors or interfaces in the form of a block diagram.

FIG. 5 shows an overview of a module according to an example embodiment of the present invention with respect to the infrastructure in the form of a block diagram.

FIG. 6 shows a perspective view of the device with a view of an open carrier board, according to an example embodiment of the present invention.

FIG. 7 shows a perspective view of the device according to FIG. 6 with closed electronics assemblies, according to an example embodiment of the present invention.

### DETAILED DESCRIPTION OF EXAMPLE EMBODIMENTS

The present invention is shown schematically on the basis of multiple exemplary embodiments and is described extensively below with reference to the figures.

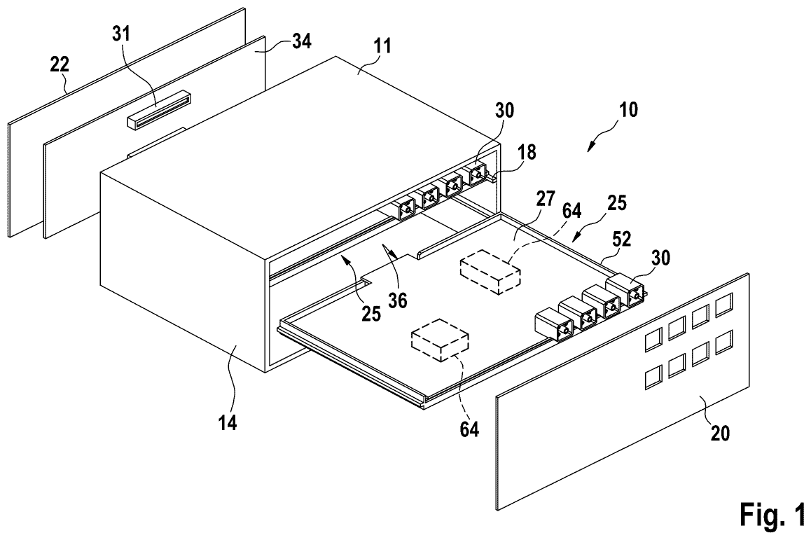

In FIG. 1, the device 10 comprises at least two electronics assemblies 25 and a housing 11 at least partially surrounding them. However, depending on the application, further electronics assemblies 25 can also be arranged exchangeably in the housing 11. The housing 11 has two side surfaces 14. The housing 11 is closed at the rear side via a rear housing cover 22, in particular by a mechanical fixation, such as a screw connection. A printed circuit board 34 is arranged in parallel with the rear housing cover 22 and perpendicularly to the exchangeable electronics assemblies 25. Plug connections 31, which establish electronic contact between the individual electronics assemblies 25 and the printed circuit board 34, are provided on the printed circuit board 34. By way of example, further electronics components (not shown explicitly), which, for example, control the communication processes, are provided on the printed circuit board 34.

The front side 20 provides access to the exchangeable electronics assemblies 25 arranged inside the device 10. The front side 20 is to be opened and closed via mechanical fixations. The front side 20 has multiple recesses through which the connectors 30 connected to the respective electronics assemblies 25 extend. The device 10 is contacted with further components in the motor vehicle via these connectors 30. Alternatively or additionally, connectors 30 could also be arranged on the rear side of the housing 11 so that the recesses are to be provided, for example, on the rear housing cover 22. The contacting of the electronics assemblies 25 with the connectors 30 would then take place via the transverse rear printed circuit board 34.

Multiple receptacles 18 are in each case provided on the inner side of the side surfaces 14 of the housing 11. These substantially rail-shaped receptacles 18 are used to receive, insert, and/or clamp the exchangeable electronics assemblies 25. For example, the electronics assembly 25 can comprise a printed circuit board 27 or an electronics unit, for example a so-called base board or motherboard, or further electronics components 64 as indicated shaded in FIG. 1 by way of example. The electronics units with associated electronics components 64 in particular comprise high-performance computer cores, which take on particularly computationally intensive functions in the motor vehicle. These functions may, for example, be autonomous or partially autonomous driving functions, infotainment, communication interfaces between different bus systems (Ethernet, CAN, LIN, etc.) or gateway functionalities, certain safety applications for granting authorization to also access the motor vehicle from the outside, for example, or further operations associated with, in particular high, computing power in the motor vehicle. The electronics components 64 are particularly preferably powerful processors, multi-core processors or highly integrated circuits (SoC, system-on-chip), which may be characterized by high power losses.

The printed circuit board 27 of the electronics assembly 25 is enclosed from at least one side by a housing 52 or a housing half 52. In the side regions, the housing half 52 ends in corresponding protrusions, which can be placed onto the receptacles 18 in the housing 11 or inserted into the receptacles 18. The housing half 52 laterally encloses the printed circuit board 27 almost completely, except for a contacting region 36 which somewhat protrudes in the direction of the rear housing cover 22 or the rear printed circuit board 34. In the inserted state of the electronics assembly 25, the contacting region 36 is received by the plug connection 31 of the rear printed circuit board 34. This results in the various electronics assemblies 25 being connected to one another via the rear printed circuit board 34.

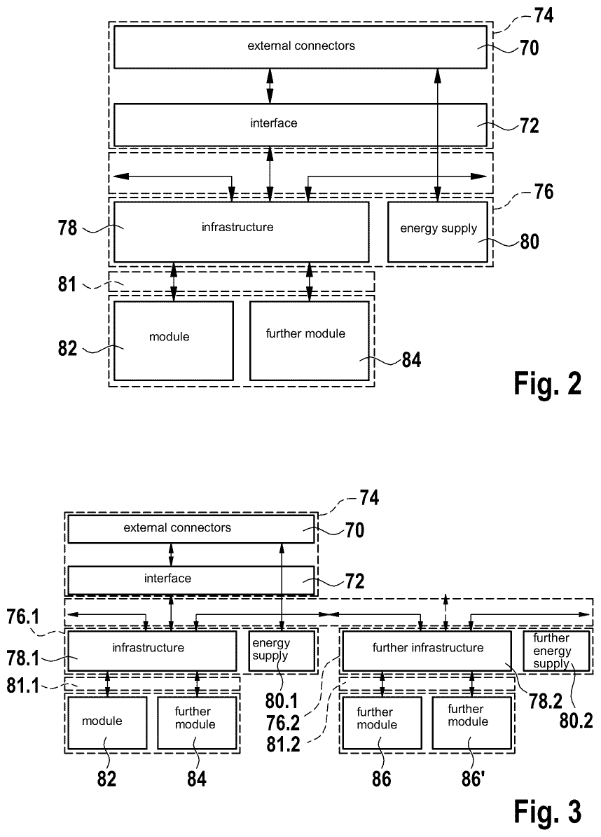

The block diagram according to FIG. 2 systematically shows the functional partitioning of the device 10. An interface board 74 comprises on the one hand external connectors 70. These external connectors preferably exchange analog signals with an interface 72. The interface 72 is likewise part of the interface board 74. The interface board 74 is preferably assembled in a project-specific manner. The interface board 74 corresponds to the rear printed circuit board 34 of FIG. 1.

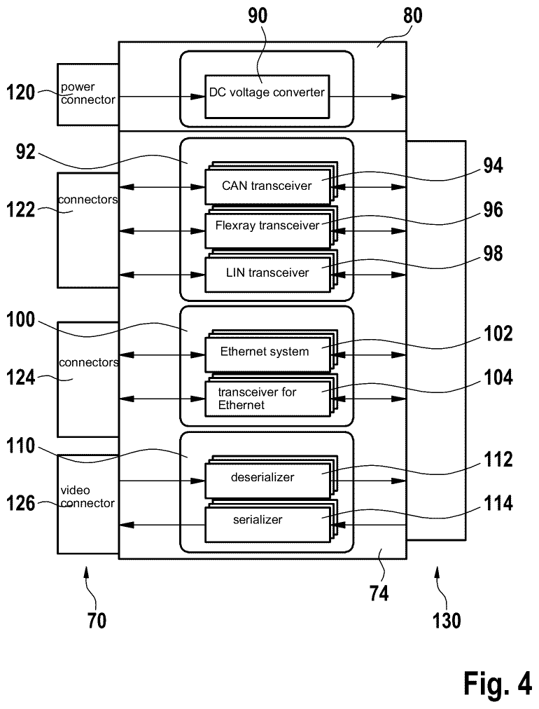

For example, a carrier board 76 comprises an infrastructure 78 and/or an energy supply 80. Alternatively, the energy supply 80 is accommodated on the rear printed circuit board 34 or the interface board 74, as indicated in FIG. 4. The infrastructure 78 in particular exchanges data digitally with the interface 72 of the interface board 74. The infrastructure 78 is also connected to a module 82 and/or a further module 84 via at least one connector 81. The infrastructure 78 is used for data distribution and monitoring. The carrier board 76 and/or the module connector 81 may be uniform components or carry-over parts that remain the same regardless of different projects (different applications for, for example, different vehicle domains such as body electronics, power train, chassis, infotainment, at least partially autonomous driving, etc.). For example, the modules 82, 84 may be so-called computing modules, which in particular comprise computing units 136, 138 or processors with high computing powers. These computing modules 82, 84 may be standardized boards that are characterized by uniform dimensions or form factors. The appropriate modules 82, 84 can be selected depending on the particular computing requirements. A change or increase in the computing power can be made possible particularly simply by exchanging the corresponding module 82, 84. The module 82, 84 may be a flexible, standardized, pluggable processor module on a base board as a possible carrier board 76. A complex printed circuit board is only used for the plug-in module or module 82, 84. On the other hand, a simpler printed circuit board can be used for the carrier board 76. Uniform interfaces 81 are used between carrier board 76 and module 82, 84. These interfaces or connectors 81 may, for example, be based on an industry standard, such as COM HCP. Other further interfaces 81 (for example PCIe, in particular Gen4, Ethernet interfaces (for example 25 Gbit), MIPI-CS or similar suitable interfaces) may also be used. This results in scalability on both sides of the interfaces, i.e., both on the side of the computing modules 82, 84 and the carrier board 76. This results in simplified upgrade/downgrade capability and cost savings potential throughout the entire life cycle of the device 10.

The exemplary embodiment according to FIG. 3 differs from that according to FIG. 2 in that still further modules 86, 86′ are to be arranged in the device 10. These further additional modules 86, 86′ are respectively connected through further infrastructure 78.2 and/or a further energy supply 80.2 (arranged either on the carrier board 76 or the rear printed circuit board 34 or interface board 74) to the interface board 74 via respective connectors 80.1, 80.2. The further infrastructure 78.2 and/or the further energy supply 80.2 may likewise be part of a further carrier board 76.2.

FIG. 4 shows an exemplary embodiment of an interface board 74. It comprises external connectors 70. A power connector 120 contacts an energy supply 80. The energy supply 80 comprises, for example, a DC voltage converter 90 or a pre-processing of the incoming energy supply. For example, an incoming voltage level between 8 V and 48 V could be converted to a 12 V output voltage. An energy supply can thus also be ensured when exchanging modules 82, 84 that have different power requirements or are characterized by a different power loss. Furthermore, corresponding filters could be provided in the energy supply 80. In addition, reverse polarity protection could, for example, be provided as part of the energy supply 80.

The interface board 74 furthermore comprises lower-speed bus interfaces 92. By way of example, a CAN transceiver 94, in particular a CAN FD transceiver, is provided and/or a Flexray transceiver 96 and/or a LIN transceiver 98. These bus systems are only mentioned by way of example and may also be changed depending on the application. Accordingly, connectors 122 are also provided for these lower-speed bus interfaces 92.

The interface board 74 furthermore comprises higher-speed bus interfaces 100. By way of example, Ethernet bus systems having different transmission speeds are mentioned here. For example, a multi-GIG Ethernet system 102 and/or an in particular 100/1000 transceiver 104 for Ethernet is provided. Depending on the application, the corresponding data connections having higher speed are to be provided with the associated connectors 124 (e.g., up to H-MTD quad (1000Base-T/10GBase-T1), or further H-MTD quads (100/1000Base-T1) or up to MATENet quad (100Base-T1)).

The interface board 74 furthermore comprises a video interface 110 with associated deserializer 112 and/or serializer 114 connected via a video connector 126 (for example, up to multiple, in particular four, HFM quads).

The exchange with the further components of the electronics assemblies 25 takes place in particular digitally via an internal interface 130.

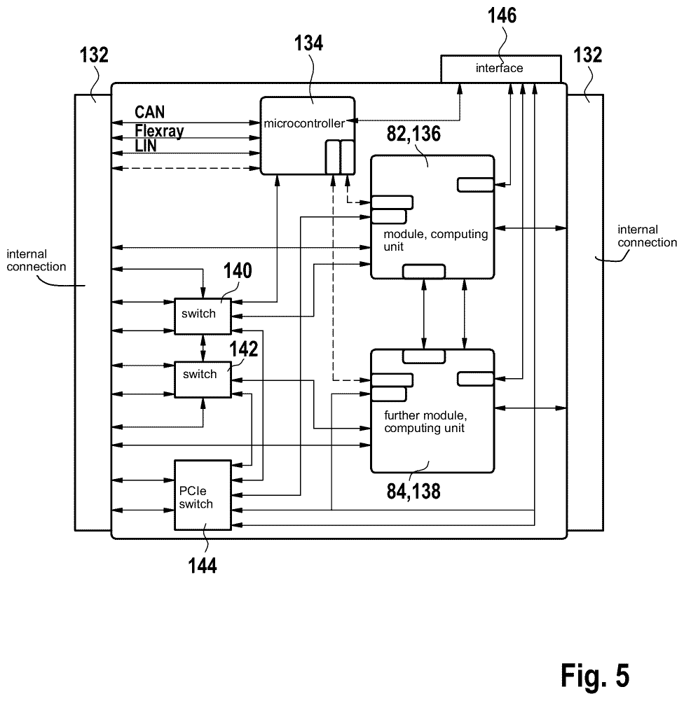

FIG. 5 shows the infrastructure 78 on the carrier board 76 or 76.1, 76.2 in more detail by way of example. The below-mentioned components of the infrastructure 78 are connected in terms of signaling via an internal connection 132. The infrastructure 78 comprises a microcontroller 134. The data of the lower-speed bus systems 92 and/or the data of the higher-speed bus systems 100 flow via the microcontroller 134. An interface 146, in particular an MT/debugger interface, is also to be controlled via the microcontroller 134 (in particular via AURORA/DAP protocol). The microcontroller 134 assumes the control of the board and/or the control of the energy supply or the associated power sequencing.

Furthermore, a switch 140, in particular an Ethernet switch, is provided, which exchanges data with the internal connection 132 (for example, via SGMII). The switch 140 is furthermore connected in terms of data to the microcontroller 134 (RGMII). Furthermore, the switch 140 is connected to the computing unit 136 of the module 82 (SGMII).

A further switch 142, in particular an Ethernet switch, is provided, which exchanges data with the internal connection 132 (for example, via SGMII protocol). The further switch 142 exchanges data with a further computing unit 138 (for example, via SGMII protocol). The two switches 140, 142 are configured to exchange data. The further switch 142 can exchange data with the internal connection 132 via a further protocol (XFI). In addition, the further switch 142 can exchange data via a PCIe switch 144 (via PCIe protocol). The PCIe switch 144 in turn exchanges data with the internal connection 132, with the further switches 140, 142, with the further computing units 136, 138 of the modules 82, 84 and/or with the interface 146 (MT/debugger), via PCIe protocol in each case.

The interface 146 (MT/debugger) in turn exchanges data with the two computing units 136, 138 (preferably via PCIe protocol), and the interface 132 exchanges data with the two computing units 136, 138 (preferably via MIPI-CSI protocol).

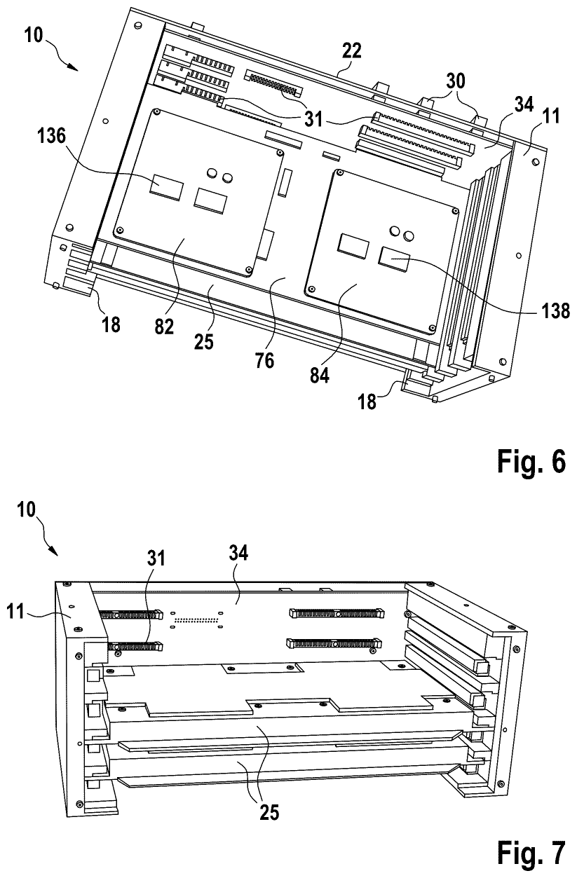

In the exemplary embodiment according to FIG. 6, the device 10 is shown from above with the housing 11 not yet closed. The rear side of the device 10 is closed by a rear housing cover 22, through which the connectors 30 extend for contacting the rear printed circuit board 34. The plug connections 31 oriented toward the inner side of the device 10 are again visible in the vertical rear printed circuit board 34 shows. The electronics assemblies 25 can be contacted via these plug connections. Provided as part of such an electronics assembly 25 is the carrier board 76, which is designed as a printed circuit board and, as described, carries, in a detachably connected manner, the two modules 82, 84 with computing units 136, 138 arranged thereon.

The exemplary embodiment according to FIG. 7 differs from that according to FIG. 6 in that the carrier board 76 is closed, for example by means of corresponding housing halves. By way of example, two electronics assemblies 25 are inserted into the device 10.

The device 10 is used in particular for exchangeable electronics components in the motor vehicle sector. In the exchangeable electronics assemblies 25 with high cooling requirements, computationally intensive functions in the motor vehicle sector can in particular be realized, such as partially autonomous or autonomous driving, communication modules, gateway functionalities, power train, body electronics, infotainment, safety applications, etc. Such functions may respectively be realized in an exchangeable electronics assembly 25. The exchangeability also allows later retrofitting of current hardware in that electronics assemblies 25 or the individual modules 82, 84 can be easily exchanged.

1-12. (canceled)

13. A device with exchangeable electronics assemblies of a motor vehicle, comprising:
at least one housing configured to at least partially enclose at least two exchangeable electronics assemblies of the motor vehicle;
at least one front side which is detachably connected to the housing and via which the exchangeable electronics assemblies arranged inside the housing can be accessed;
a rear housing cover; and
a rear printed circuit board which is aligned transversely to the at least two electronics assemblies and serves to contact the at least two exchangeable electronics assemblies;
wherein at least one of the exchangeable electronics assemblies includes at least one carrier board with an infrastructure, and at least one module with at least one computing unit including a processor, connected to the carrier board.

14. The device according to claim 13, wherein vehicle functions are realized in the module.

15. The device according to claim 13, wherein the at least one of the electronics assemblies includes at least one contacting region, and/or the rear printed circuit board includes at least one plug connection for receiving a contacting region of the at least one of the electronics assemblies.

16. The device according to claim 13, wherein the infrastructure includes at least one unit for data distribution or data monitoring, the at least one unit including: (i) at least one switch and/or (ii) at least one microcontroller and/or (iii) at least one interface and/or (iv) at least one internal connection or interface and/or (v) at least one energy supply and/or (vi) at least one module connector and/or (vii) at least one unit for safety monitoring and/or (viii) at least one unit data security including a firewall and/or (ix) an interface for data acquisition and/or (x) an interface for programming support.

17. The device according to claim 13, wherein: (i) data of at least one bus system flow via a microcontroller arranged on the carrier board, and/or (ii) the microcontroller is connected for data exchange to at least one switch and/or to at least one module including an associated computing unit.

18. The device according to claim 13, wherein at least one connector is provided between the carrier board and the module and is configured a uniform interface.

19. The device according to claim 13, wherein an interface board is provided as the rear printed circuit board, and includes: (i) at least one external connector and/or at least one power connector for an energy supply and/or (ii) at least one internal interface for digital signals, and/or (iii) at least one connector for at least one bus system and/or (iv) at least one video connector and/or (v) at least one video interface and/or (vi) at least one bus interface and/or (vii) at least one transceiver and/or (viii) at least one serializer or deserializer.

20. The device according to claim 13, wherein at least parts of an energy supply are arranged on the rear printed circuit board or on the interface board.

21. The device according to claim 13, wherein the module is a plug-in module.

22. The device according to claim 13, wherein the at least one module includes a plurality of modules having uniform geometric dimensions and/or uniform interfaces.

23. The device according to claim 13, further comprising a further carrier board.

24. The device according to claim 20, wherein the energy supply includes at least one voltage converter and/or filters and/or reverse polarity protection.
